(19) United States
(12) Patent Application Publication
(10) Pub. No.: US 2012/0127681 A1
(43) Pub. Date: May 24, 2012

(54) SOLDERING CONNECTING PIN, SEMICONDUCTOR PACKAGE SUBSTRATE AND METHOD OF MOUNTING SEMICONDUCTOR CHIP USING THE SAME

(75) Inventors: Ji Man RYU, Gyunggi-do (KR); Kwan Ho LEE, Seoul (KR); Kyu Bum HAN, Gyunggi-do (KR); Seog Moon CHOI, Seoul (KR); Jin Su KIM, Seoul (KR)

(73) Assignee: SAMSUNG ELECTRO-MECHANICS CO., LTD., Gyunggi-do (KR)

(21) Appl. No.: 13/010,709

(22) Filed: Jan. 20, 2011

(30) Foreign Application Priority Data
Nov. 24, 2010 (KR) 10-2010-0117694

(51) Int. Cl. H01R 9/00; H05K 3/00; H01B 5/00

(52) U.S. Cl. 361/772; 174/126.1; 29/846

(57) ABSTRACT

Disclosed herein are a soldering connecting pin, a semiconductor package substrate and a method of mounting a semiconductor chip using the same. A semiconductor chip is mounted on the printed circuit board using the soldering connecting pin inserted into a through-hole of the printed circuit board, thereby preventing deformation of the semiconductor package substrate and fatigue failure due to external shocks.

### CROSS REFERENCE TO RELATED APPLICATION

This application claims the benefit of Korean Patent Application No. 10-2010-0117694, filed on Nov. 24, 2010, entitled “Soldering Connecting Pin, Semiconductor Package Substrate and Method of Mounting Semiconductor Chip Using the Same”, which is hereby incorporated by reference in its entirety into this application.

### BACKGROUND OF THE INVENTION

1. Technical Field

The present invention relates to a soldering connecting pin, a semiconductor package substrate and a method of mounting a semiconductor chip using the same.

2. Description of the Related Art

In accordance with the recent trend of compactness and slimness of electronic devices, the demand for mounting technologies using a semiconductor package substrate on which components may be mounted, at high density, with high accuracy, and with high integration has increased. In accordance with the trend of high-density, high-accuracy, and high-integration of the components, accuracy and completeness of manufacture of the semiconductor package substrate are required and bonding reliability between a semiconductor chip and a substrate is very important.

In addition, as portable multimedia devices such as a smart phone, an MP3, and the like, has commonly spread, the demand for security against external shocks has increased in the semiconductor package substrate used for the portable multimedia devices.

The semiconductor package substrate according to the prior art is configured to include a printed circuit board 100 circuit patterns 110 and a through-hole 120 formed therein and a semiconductor chip 200 mounted on the printed circuit board 100 by inserting and soldering an external lead 210 thereof into the through-hole 120, as shown in FIG. 1.

The semiconductor chip 200 and the printed circuit board 100 are bonded to each other through a solder 130 which is melted by being heated within a reflow apparatus at a high temperature. At this time, thermal stress is generated due to differences in thermal expansion coefficient among the semiconductor chip 200, the printed circuit board 100, and the solder 130. The thermal stress has caused problems such as deformation of the completed semiconductor package substrate and failure of the solder 130 connecting the semiconductor chip 200 to the printed circuit board 100.

In addition, in the structure according to the prior art bonding the external lead 210 of the semiconductor chip 200 to the printed circuit board 100 by filling the through-hole 120 with the solder 130, when a continuous external shock is applied thereto, there was a considerable risk of fatigue failure, thereby causing instability of the semiconductor package substrate.

### SUMMARY OF THE INVENTION

The present invention has been made in an effort to provide a soldering connecting pin that includes a pin head having a hole formed therein; and a plurality of pin bodies formed on a lower surface of the pin head, wherein the pin body includes a support extended downward from the pin head and a bonding portion extended to be bent from the support, used for mounting a semiconductor chip on a printed circuit board to reduce thermal stress and prevent fatigue failure due to external shocks, thereby improving the stability of a semiconductor package substrate.

A soldering connecting pin according to a first preferred embodiment of the present invention includes: a pin head having a hole formed therein; and a plurality of pin bodies formed on a lower surface of the pin head, wherein the pin body includes a support extended downward from the pin head and a bonding portion extended to be bent from the support.

The pin body may further include a latch protruded to the outside between the support and the bonding portion.

The plurality of pin bodies may be formed at the same interval along the circumference of the hole.

The plurality of pin bodies may be formed to have the same shape.

The bonding portion may be extended to be bent plural times from the support.

The pin head and the pin body may be made of a metal.

A semiconductor package substrate according to a second preferred embodiment of the present invention includes: a printed circuit board having circuit patterns and a through-hole formed therein; a soldering connecting pin including a pin head having a hole formed therein and a plurality of pin bodies formed on a lower surface of the pin head, the pin body including a support extended downward from the pin head and a bonding portion extended to be bent from the support, and the pin body being inserted into the through-hole; a semiconductor chip mounted on the printed circuit board by inserting an external lead thereof into the soldering connecting pin; and a first solder connecting the bonding portion of the soldering connecting pin to the external lead.

The pin body may further include a latch latched on a lower side of the through-hole into which the pin body is inserted and protruded to the outside between the support and the bonding portion.

A length of the support may correspond to that of the through-hole of the printed circuit board into which the pin body is inserted.

The plurality of pin bodies may be formed in equal intervals along the circumference of the hole.

The plurality of pin bodies may be formed to have the same shape.

The first solder may connect a lower end of the bonding portion to the external lead.

The semiconductor package substrate may further include a second solder connecting the pin head of the soldering connecting pin to the printed circuit board.

A method of mounting a semiconductor chip according to a third preferred embodiment of the present invention includes: (A) preparing a printed circuit board having circuit patterns and a through-hole formed therein; (B) inserting a soldering connecting pin into the through-hole, the soldering connecting pin including a pin head having a hole formed therein and a plurality of pin bodies formed on a lower surface of the pin head and the pin body including a support extended downward from the pin head and a bonding portion extended to be bent from the support; (C) inserting an external lead of a semiconductor chip into the soldering connecting pin; and (D) soldering the bonding portion of the soldering connecting pin and the external lead.

Step (D) may include soldering a lower end of the bonding portion and the external lead.

The method of mounting a semiconductor chip may further include (E) soldering the pin head of the soldering connecting pin and the printed circuit board, after step (D).

### BRIEF DESCRIPTION OF THE DRAWINGS

FIG. 1 is a cross-sectional view of a semiconductor package substrate according to the prior art;

FIGS. 2 to 4 are perspective views of a soldering connecting pin according to a preferred embodiment of the present invention;

FIGS. 5 to 7 are cross-sectional views of a semiconductor package substrate according to a preferred embodiment of the present invention; and

FIGS. 8 to 12 are cross-sectional views showing a method of mounting a semiconductor chip according to a preferred embodiment of the present invention according to process order.

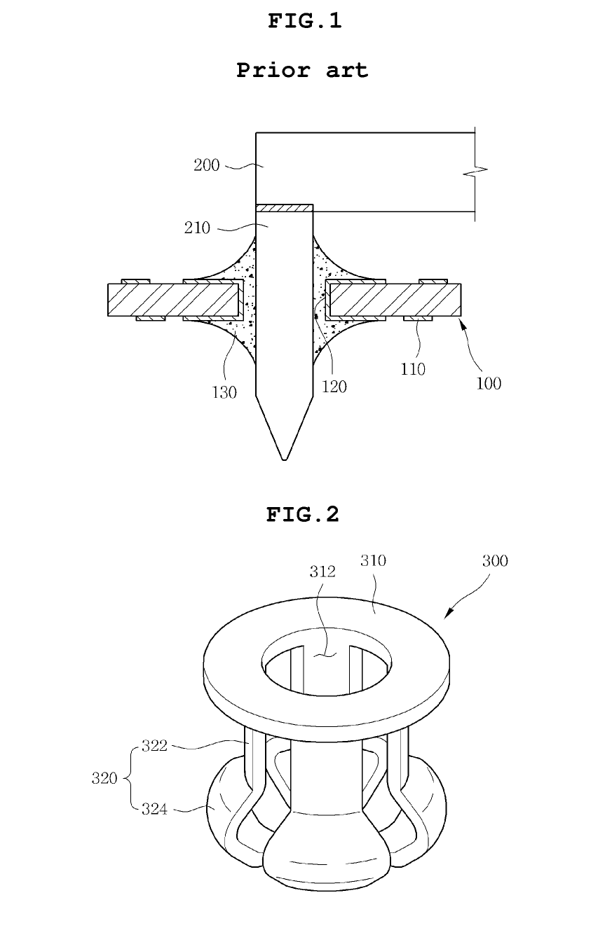

### DESCRIPTION OF THE PREFERRED EMBODIMENTS

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, a detailed description thereof will be omitted.

FIGS. 2 to 4 are perspective views showing a soldering connecting pin according to a preferred embodiment of the present invention. Hereinafter, a soldering connecting pin according to a preferred embodiment of the present invention will be described with reference to the accompanying drawings.

As shown in FIG. 2, a soldering connecting pin 300 according to a preferred embodiment of the present invention is configured to include a pin head 310 having a hole 312 formed therein and a plurality of pin bodies 320 formed on a lower surface of the pin head 310, wherein the pin body 320 includes a support 322 extended downward from the pin head 310 and a bonding portion 324 extended to be bent from the support 322.

First, the pin head 310, which is a portion positioned at an upper portion of the printed circuit board 100 when the soldering connecting pin 300 is inserted into the through-hole 120 formed in the printed circuit board 100, is formed with the hole 312 corresponding to the through-hole 120. The size of the pin head 310 should be larger than that of the though-hole so that the pin head 310 is latched onto the through-hole 120 during the insertion of the soldering connecting pin 300 into the through-hole 120, thereby preventing the soldering connecting pin 300 from passing through the through-hole 120. A shape of the pin head 310 may be several shapes such as a circular shape, a rectangular shape, a diamond shape, and the like.

The hole 312 formed in the pin head 310 is inserted with an external lead 210 of a semiconductor chip 200, or the like, as described below. The size of the hole 312 is formed to be smaller than that of the though-hole 120 so that the pin body 320 extended downward from the pin head 310 may be inserted into the though-hole 120. In order to easily insert the soldering connecting pin 300 into the through-hole 120, a shape of the hole 312 may be preferably formed to correspond to that of the through-hole 120, and may be several shapes such as a circular shape, a rectangular shape, a diamond shape, and the like.

The pin body 320 which is inserted into the through-hole 120 of the printed circuit board 100 is configured of the support 322 and the bonding portion 324. A plurality of pin bodies 320 are formed on the lower surface of the pin head 310. Hereinafter, each component of the pin body 320 will be described.

First, the support 322 is extended downward from the pin head 310. The support 322 which contacts an inner side of the through-hole 120 when the soldering connecting pin 300 is inserted into the through-hole 120 of the printed circuit board 100 may be electrically connected to the printed circuit board 100.

The bonding portion 324 which is bonded to the external lead 210 of the semiconductor chip 200 through the solder is extended to be bent from the support 322. The bent part of the bonding portion 324 absorbs thermal stress generated at the time of soldering to prevent deformation of the substrate and failure of the solder. In addition, the bent part of the bonding portion 324 absorbs external shocks to prevent fatigue failure of a solder bonding portion.

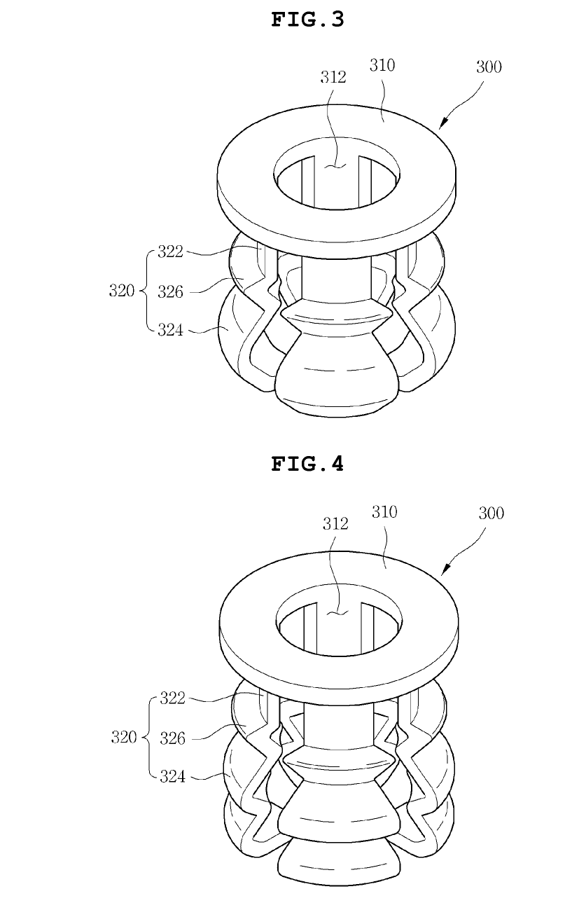

At this time, the bonding portion 324 may be extended to be bent plural times as shown in FIG. 3. The bonding portion 324 has plural bend parts to more effectively absorb thermal stress and external shocks.

Further, the pin body 320 may further include a latch 326 protruded to the outside between the support 322 and the bonding portion 324, as shown in FIG. 4. The latch 326 is latched on a lower side of the through-hole 120 when the soldering connecting pin 300 is inserted into the through-hole 120 of the printed circuit board 100, thereby preventing the soldering connecting pin 300 from being separated from the printed circuit board 100.

In addition, a plurality of pin bodies 320 are formed at the same interval along the circumference of the hole 312 of the pin head 310. The plurality of pin bodies 320 are formed at the same interval along the circumference of the hole 312 of the pin head 310 to enclose the external lead 210 inserted into the hole 312 of the soldering connecting pin 300. The external lead 210 is connected to the plurality of bonding portions 324 enclosing the external lead 210 through the solder to be more firmly coupled thereto.

In addition, the plurality of pin bodies 320 may be formed to have the same shape. The plurality of pin bodies 320 are formed to have the same size and same shape, such that the soldering connecting pin 300 has a hollow shape.

At this time, the pin head 310 and the pin body 320 may be made of a metal. The soldering connecting pin 300 is made of a metal to electrically connect the printed circuit board 100 to the semiconductor chip 200. Copper (Cu) having excellent electric conductivity and processability may be preferably used as the metal; however, the present invention is not necessarily limited thereto. All metals having electric conductivity may be used.

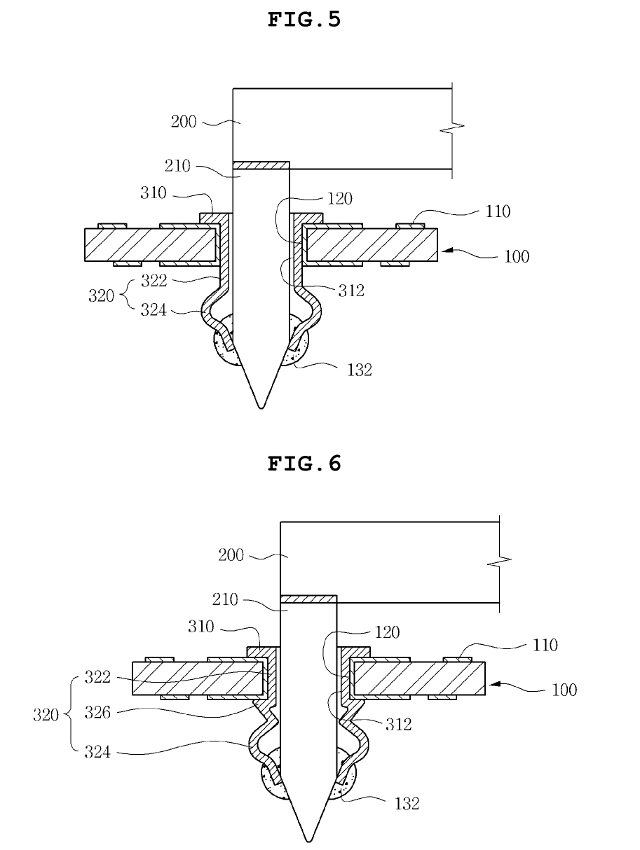

FIGS. 5 and 6 are cross-sectional views showing a semiconductor package substrate according to a preferred embodiment of the present invention.

A semiconductor package substrate according to a preferred embodiment of the present invention is configured to include a printed circuit board 100 having circuit patterns 110 and a through-hole 120 formed therein, a soldering connecting pin 300 inserted into the through-hole 120, a semiconductor chip 200 mounted on the printed circuit board 100 by inserting an external lead 210 thereof into the soldering connecting pin 300, and a first solder 132 connecting the bonding portion 324 of the soldering connecting pin 300 to the external lead 210, as shown in FIG. 5. Hereinafter, each component of the semiconductor package substrate will be described.

First, the printed circuit board (PCB) 100 includes the circuit patterns 110 and the through-hole 120. A printed circuit board (PCB) 100 electrically interconnects components mounted thereon through an internal circuit formed on an insulating material such as a phenol resin insulating plate, an epoxy resin insulating plate, or the like, supplies power, and the like to the components and at the same time, mechanically fixes the components. As the printed circuit board, there are a single-sided PCB in which the circuit patterns are formed only on one side of an insulating material, a double-sided PCB in which the circuit patterns are formed on both sides thereof, and a multi layered printed circuit board (MLB) in which the circuit patterns are formed in a multilayer. Although FIG. 5 has shown the double-side printed circuit board in which the circuit patterns are formed on both sides of the insulating material, the present invention is not limited thereto but may use the multi layered printed circuit board having at least two circuit patterns.

The circuit patterns 110 formed on the printed circuit board 100 is electrically connected to the soldering connecting pin 300 to transmit and receive electrical signals to and from and external components bonded through the soldering and the soldering connecting pin 300.

Further, an inner portion of the through-hole 120 formed in the printed circuit board 100 is copper plated, such that the circuit patterns 110 and the soldering connecting pin 300 are electrically interconnected.

Next, the soldering connecting pin 300 is directly connected to the external lead 210 of the semiconductor chip 200 mounted on the semiconductor package substrate through the soldering and absorbs thermal stress and external shocks through the bent part of the bonding portion 324 as described above to prevent deformation of the semiconductor package substrate and fatigue failure of the solder. When the soldering connecting pin 300 is inserted into the through-hole 120, the pin body 320 thereof contacts the through-hole 120 copper plated in the inner portion thereof to be electrically connected to the printed circuit board 100. In addition, the pin head 310 of the soldering connecting pin 300 contacts an upper portion of the circuit pattern 110 formed in the vicinity of the through-hole 120 to be electrically connected to the circuit patterns 110.

At this time, the pin body 320 may further include the latch 326 latched on the lower side of the through-hole 120 protruded to the outside between the support 322 and the bonding portion 324, as shown in FIG. 6. The latch 326 is latched on the lower side of the through-hole 120, thereby more firmly coupling the soldering connecting pin 300 to the printed circuit board 100.

In addition, a length of the support 322 of the soldering connecting pin 300 corresponds to that of the through-hole 120 of the printed circuit board 100, such that the latch 326 is latched on the lower side of the through-hole 120 in a state in which the soldering connecting pin 300 is inserted into the through-hole 120.

Further, the plurality of pin bodies 320 are formed at the same intervals and have the same shape along the circumference of the hole 312 of the pin head 310, such that the soldering connecting pin 300 has a hollow shape enclosing the external lead 210 of the semiconductor chip 200.

The semiconductor chip 200 is mounted on the semiconductor package substrate by inserting the external lead 210 thereof into the soldering pin 300. The semiconductor chip 200 may be an insulated gate bipolar transistor (IGBT), diode, or the like. However, the semiconductor chip is not limited thereto but includes all other electronic elements such as an active element, a passive element, or the like. The external lead 210 of the semiconductor chip 200 is bonded to the soldering connecting pin 300 through the solder to be electrically connected to the circuit patterns 110 formed on the printed circuit board 100.

The first solder 132 connects the bonding portion 324 of the soldering connecting pin 300 to the external lead 210 of the semiconductor chip 200. The first solder 132 serves to fix the semiconductor chip 200 to the semiconductor package substrate, simultaneously with electrically connecting the semiconductor chip 200 to the semiconductor package substrate. The first solder 132 may be made of a mixture such as tin/lead (Sn/Pb), tin/silver/copper (Sn/Ag/Cu), tin/silver (Sn/Ag), tin/copper (Sn/Cu), tin/bismuth (Sn/Bi), tin/zinc/bismuth (Sn/Zn/Bi), tin/silver/bismuth (Sn/Ag/Bi), and the like.

At this time, the first solder 132 may preferably connect a lower end of the bonding portion 324 of the soldering connecting pin 300 to the external lead 210 of the semiconductor chip 200, as shown in FIG. 6. The bent part of the bonding portion 324 is not formed with the first solder 132, such that it may effectively absorb thermal stress and external shocks.

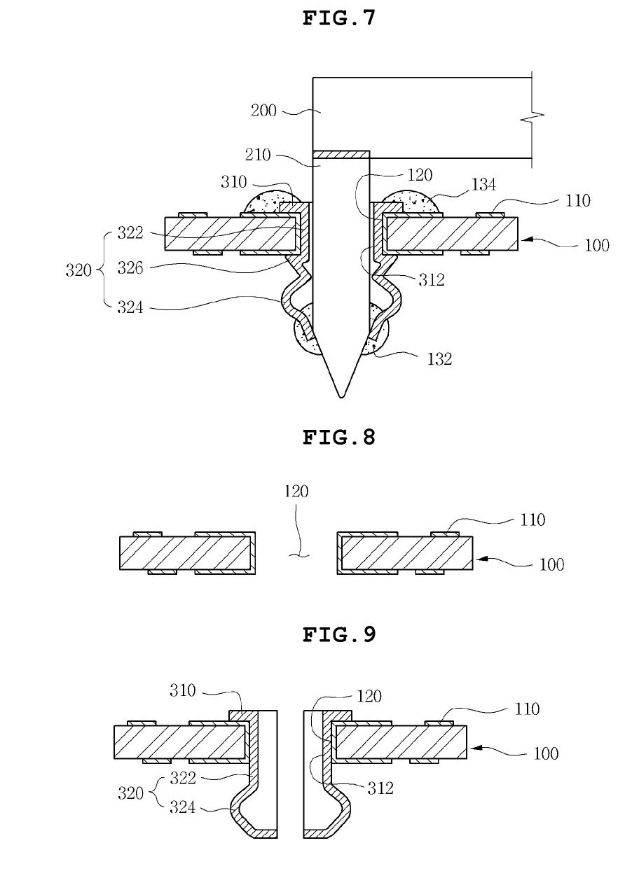

In addition, the semiconductor package substrate may further include a second solder 134 connecting the pin head 310 of the soldering connecting pin 300 to the printed circuit board 100, as shown in FIG. 7. The second solder 134 may more firmly couple the soldering connecting pin 300 to the printed circuit board 100 and may also electrically connect the circuit patterns 110 formed on the printed circuit board 100 to the pin head 310.

FIGS. 8 to 12 are cross-sectional views showing a method of mounting a semiconductor chip according to a preferred embodiment of the present invention according to process order.

A method of mounting a semiconductor chip 200 according to a preferred embodiment of the present invention includes: (A) preparing the printed circuit board 100 having the circuit patterns 110 and the through-hole 120 formed therein, (B) inserting the soldering connecting pin 300 into the through-hole 120, the soldering connecting pin 300 including the pin head 310 having the hole 312 formed therein and the plurality of pin bodies 320 formed on the lower surface of the pin head 310, and the pin body 320 including the support 322 extended downward from the pin head 310 and the bonding portion 324 extended to be bent from the support 322, (C) inserting the external lead 210 of the semiconductor chip 200 into the soldering connecting pin 300, and (D) soldering the bonding portion 324 of the soldering connecting pin 300 and the external lead 210. Hereinafter, a method of mounting a semiconductor chip 200 according to a preferred embodiment of the present invention will be described according to the process order.

First, the printed circuit board 100 having the circuit patterns 110 and the through-hole 120 formed therein is prepared, as shown in FIG. 8. The circuit patterns 110 may be formed using a subtractive method, an additive method, a semi-additive method, and the like. The inner portion of the through-hole 120 is also copper plated to be electrically connected to the circuit patterns 110. Meanwhile, the through-hole 120 may be formed by drilling using a computer numeral control drill (CNC), CO₂, YAG laser.

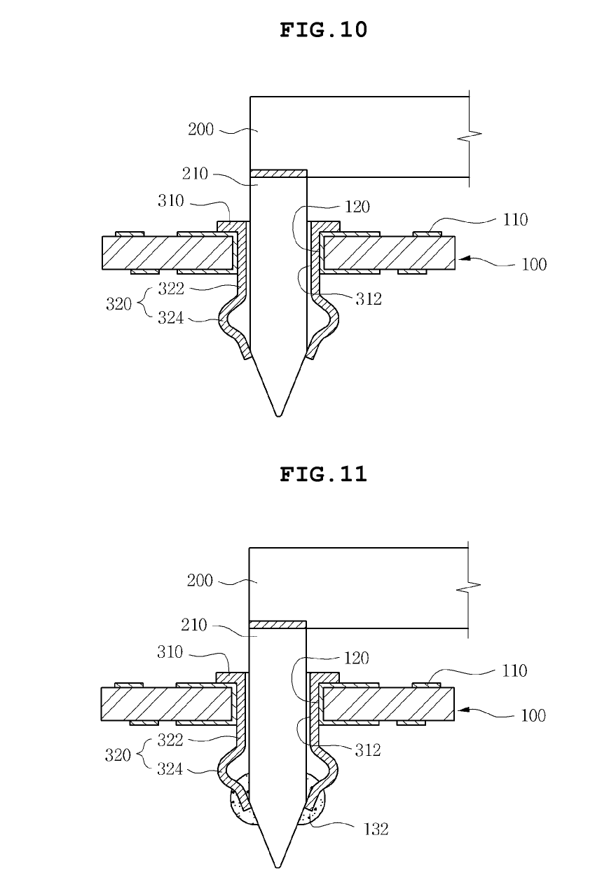

Next, the soldering connecting pin 300 is inserted into the through-hole 120 of the printed circuit board 100, as shown in FIG. 9. After the soldering connecting pin 300 is connected to the through-hole 120, the external lead 210 of the semiconductor chip 200 is inserted into the hole 312 formed in the pin head 310, as shown in FIG. 10.

Then, the bonding portion 324 of the soldering connecting pin 300 and the external lead 210 are soldered, as shown in FIG. 11. The first solder 132 connecting the external lead 210 to the soldering connecting pin 300 is formed through the soldering. A portion of the soldering connecting pin 300 and the external lead 210 are soldered without filling the entirety of the through-hole 120 with the solder, thereby reducing the thermal stress due to the difference in thermal expansion coefficient. The soldering may be performed through a reflow process heating the first solder 132 at a melting temperature or more for twenty to thirty minutes.

At this time, the lower end of the soldering connecting pin 300 and the external lead 210 may be preferably soldered. As described above, the bent part of the bonding portion 324 is not filled with the solder, such that it may effectively absorb thermal stress and external shocks.

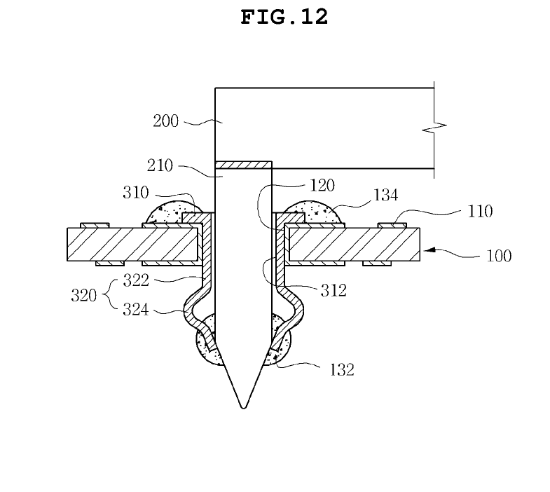

In addition, the pin head 310 of the soldering connecting pin 300 and the printed circuit board 100 may be additionally soldered, as shown in FIG. 12. The second solder 134 connecting the pin head 310 to the printed circuit board 100 is formed through soldering. The second solder 134 may be formed before or after the process of soldering the bonding portion 324 of the soldering connecting pin 300 and the external lead 210.

The soldering connecting pin according to the preferred embodiments of the present invention is configured of the pin head having the hole formed therein and the pin body made of the support and the bonding portion to solder only the bonding portion of the soldering connecting pin and the external lead of the semiconductor chip when the semiconductor chip is mounted, thereby making it possible to reduce thermal stress. In addition, the bent part at the bonding portion may absorb the thermal stress and the external shocks.

Further, the pin body further includes the latch protruded to the outside between the support and the bonding portion, thereby firmly coupling the soldering connecting pin to the printed circuit board.

Furthermore, the bonding portion is extended to be bent plural times from the support, thereby making it possible to effectively absorb the external shocks.

The semiconductor package substrate according to the preferred embodiment of the present invention includes the printed circuit board having the circuit patterns and the through-hole formed therein, the soldering connecting pin inserted into the through-hole, and the semiconductor chip mounted through the first solder by inserting the external lead thereof into the soldering connecting pin, thereby preventing deformation of the substrate due to thermal stress and fatigue failure due to external shocks.

In addition, the first solder connects the lower end of the bonding portion of the soldering connecting pin to the external lead, thereby making it possible to effectively absorb the external shocks.

Further, the semiconductor package substrate further includes the second solder connecting the pin head of the soldering connecting pin to the printed circuit board, thereby making it possible to more firmly couple the soldering connecting pin to the printed circuit board.

Although the preferred embodiments of the present invention have been disclosed for illustrative purposes, they are for specifically explaining the present invention and thus the soldering connecting pin, the semiconductor package substrate and the method of mounting a semiconductor chip using the same according to the present invention are not limited thereto, but those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A soldering connecting pin, comprising:
a pin head having a hole formed therein; and
a plurality of pin bodies formed on a lower surface of the pin head,
wherein the pin body includes a support extended downward from the pin head and a bonding portion extended to be bent from the support.

2. The soldering connecting pin as set forth in claim 1, wherein the pin body further includes a latch protruded to the outside between the support and the bonding portion.

3. The soldering connecting pin as set forth in claim 1, wherein the plurality of pin bodies are formed at the same interval along the circumference of the hole.

4. The soldering connecting pin as set forth in claim 1, wherein the plurality of pin bodies are formed to have the same shape.

5. The soldering connecting pin as set forth in claim 1, wherein the bonding portion is extended to be bent plural times from the support.

6. The soldering connecting pin as set forth in claim 1, wherein the pin head and the pin body are made of a metal.

7. A semiconductor package substrate comprising:
a printed circuit board having circuit patterns and a through-hole formed therein;
a soldering connecting pin including a pin head having a hole formed therein and a plurality of pin bodies formed on a lower surface of the pin head, the pin body including a support extended downward from the pin head and a bonding portion extended to be bent from the support, and the pin body being inserted into the through-hole;
a semiconductor chip mounted on the printed circuit board by inserting an external lead thereof into the soldering connecting pin; and
a first solder connecting the bonding portion of the soldering connecting pin to the external lead.

8. The semiconductor package substrate as set forth in claim 7, wherein the pin body further includes a latch latched on a lower side of the through-hole into which the pin body is inserted and protruded to the outside between the support and the bonding portion.

9. The semiconductor package substrate as set forth in claim 7, wherein a length of the support corresponds to that of the through-hole of the printed circuit board into which the pin body is inserted.

10. The semiconductor package substrate as set forth in claim 7, wherein the plurality of pin bodies are formed at the same interval along the circumference of the hole.

11. The semiconductor package substrate as set forth in claim 7, wherein the plurality of pin bodies are formed to have the same shape.

12. The semiconductor package substrate as set forth in claim 7, wherein the first solder connects a lower end of the bonding portion to the external lead.

13. The semiconductor package substrate as set forth in claim 7, further comprising a second solder connecting the pin head of the soldering connecting pin to the printed circuit board.

14. A method of mounting a semiconductor chip, comprising:
(A) preparing a printed circuit board having circuit patterns and a through-hole formed therein;
(B) inserting a soldering connecting pin into the through-hole, the soldering connecting pin including a pin head having a hole formed therein and a plurality of pin bodies formed on a lower surface of the pin head, and the pin body including a support extended downward from the pin head and a bonding portion extended to be bent from the support;
(C) inserting an external lead of a semiconductor chip into the soldering connecting pin; and
(D) soldering the bonding portion of the soldering connecting pin and the external lead.

15. The method of mounting a semiconductor chip as set forth in claim 14, wherein step (D) includes soldering a lower end of the bonding portion and the external lead.

16. The method of mounting a semiconductor chip as set forth in claim 14, further comprising (E) soldering the pin head of the soldering connecting pin and the printed circuit board, after step (D).
